(19) United States
(12) Patent Application Publication
(10) Pub. No.: US 2016/0028037 A1
(43) Pub. Date: Jan. 28, 2016

(54) TANDEM ORGANIC LIGHT EMITTING DEODE DEVICE AND DISPLAY DEVICE

(71) Applicant: BOE TECHNOLOGY GROUP CO., LTD., Beijing (CN)

(72) Inventor: Chang Yen WU, Beijing (CN)

(21) Appl. No.: 14/435,973

(22) PCT Filed: Sep. 20, 2014
(86) PCT No.: PCT/CN2014/086995

§ 371 Date: Apr. 15, 2015

(30) Foreign Application Priority Data
Nov. 5, 2013 (CN) 201310544720.X

(51) Int. Cl. H01L 51/50; H01L 27/32; H01L 51/52

(52) U.S. Cl. CPC H01L 51/5044; H01L 51/5203; H01L 51/5072; H01L 51/5056; H01L 51/5218; H01L 51/5234; H01L 51/5088; H01L 51/5092; H01L 51/5221; H01L 51/5206; H01L 51/5068; H01L 51/5084; H01L 27/3209; H01L 51/5265; H01L 27/3204; H01L 27/3244

(57) ABSTRACT

A tandem OLED device and a display device are disclosed. The tandem OLED device includes a reflective electrode and a transmissive electrode; n organic emissive layers disposed between the reflective electrode and the transmissive electrode, wherein n is an integer equal to or greater than 2; and a connecting unit disposed between every two neighboring organic light emitting layers. A distance h between the two neighboring organic light emitting layers satisfies the following equation: (λ2−λ1)≦h≦(λ2−λ1).

### FIELD OF THE ART

Embodiments of the invention relate to a Tandem Organic Light Emitting Diode (Tandem OLED) device and a display device.

### BACKGROUND

OLEDs have the advantages of simple fabrication process, low cost, arbitrarily adjustable colors in the range of visible light, easily fabricated in large area and being flexible and are the most prospective technology in the display area. Conventional OLED devices comprise a first electrode, a second electrode and an organic light emitting layer disposed between the first and second electrodes, where one of the first and second electrodes is an anode and the other is a cathode. Auxiliary functional layers such as a hole injection layer and a hole transmission layer are generally included between the anode and the organic light emitting layer, and auxiliary functional layers such as electron injection layer and electron transmission layer are usually included between the cathode and the organic light emitting layer.

A Tandem OLED is a high efficiency OLED device developed on the basis of conventional OLED devices by stacking multiple of conventional OLED devices in series through connecting layers.

However, light field of the conventional OLED devices is highly directional, that is, luminous intensity is seriously attenuated when viewing angle is changed.

### SUMMARY

Embodiments of the invention provide a tandem OLED device and a display device, in order to overcome the problem of luminous intensity being seriously attenuated when viewing angle is changed.

To solve the above technical problem, the following technical solution is employed.

A first aspect of the invention provides a tandem OLED device, comprising: a reflective electrode, a transmissive electrode, n organic emissive layers disposed between the reflective electrode and the transmissive electrode, where n is an integer equal to or greater than 2, and a connecting unit disposed between every two neighboring organic light emitting layers. A distance h between two neighboring organic light emitting layers satisfies the following equation: ⅛(λ2−λ1)≦h≦⅓(λ2−λ1), where the organic light emitting layer of the two neighboring organic light emitting layers which is closer to the reflective electrode is a first organic light emitting layer, λ1 is a wavelength with the maximum energy of a spectrum energy distribution curve of light emitted by the first organic light emitting layer. The organic light emitting layer of the two neighboring organic light emitting layers which is closer to the transmissive electrode is a second organic light emitting layer, λ2 is a wavelength with the maximum energy of a spectrum energy distribution curve of light emitted by the second organic light emitting layer, and λ2>λ1.

Another aspect of the invention provides a display device comprising the above tandem OLED device.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 schematically illustrates a configuration of a tandem OLED device in accordance with an embodiment of the invention;

FIG. 2 schematically illustrates configuration of a connecting unit in accordance with an embodiment of the invention;

FIG. 3 schematically illustrates configuration of a connecting unit in accordance with an embodiment of the invention;

FIG. 4 schematically illustrates a configuration of a tandem OLED device in accordance with an embodiment of the invention;

FIG. 5 is a plot illustrating a relationship between a luminous intensity and a connecting unit thickness when simulating a tandem OLED device in accordance with an embodiment of the invention;

FIG. 6 is a diagram schematically illustrating different viewing angles when simulating the tandem OLED device of FIG. 5.

### DETAILED DESCRIPTION

In order to make objects, technical details and advantages of the embodiments of the invention apparent, the technical solutions of the embodiment will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

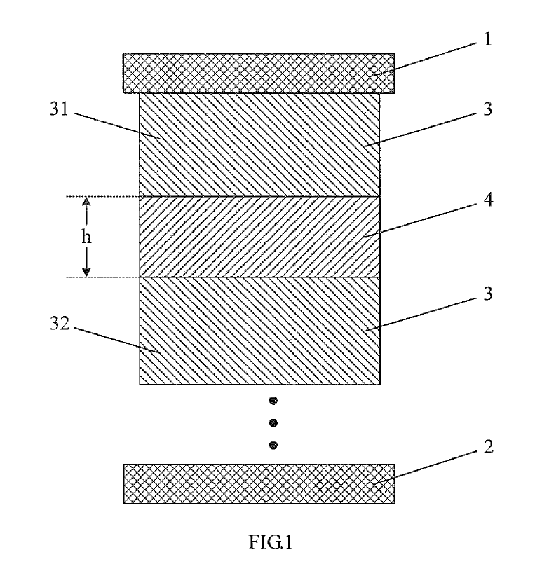

As illustrated in FIG. 1, an embodiment of the invention provides a tandem OLED device, comprising: a reflective electrode 1; a transmissive electrode 2; and n organic emissive layers 3 disposed between the reflective electrode 1 and the transmissive electrode 2, where n is an integer equal to or greater than 2. Each of the organic emissive layers 3 comprises a luminophor, which is of a material capable of emitting light. The tandem OLED device further comprises a connecting unit 4 disposed between every two neighboring organic light emitting layers 3, wherein the connecting unit 4 is configured for connecting the two neighboring organic light emitting layers 3.

A distance h between the two neighboring organic light emitting layers 3 satisfies the following equation: ⅛(λ2−λ1)≦h≦⅓(λ2−λ1). That is, a thickness of the connecting unit 4 is h.

An organic light emitting layer of the above two neighboring organic light emitting layers 3 which is closer to the reflective electrode 1 is a first organic light emitting layer 31, wherein λ1 is a wavelength with the maximum energy of a spectrum energy distribution curve of light emitted by the first organic light emitting layer 31. An organic light emitting layer of the two neighboring organic light emitting layers which is closer to the transmissive electrode 2 is a second organic light emitting layer 32, wherein λ2 is a wavelength with the maximum energy of a spectrum energy distribution curve of light emitted by the second organic light emitting layer 32, and λ2>λ1.

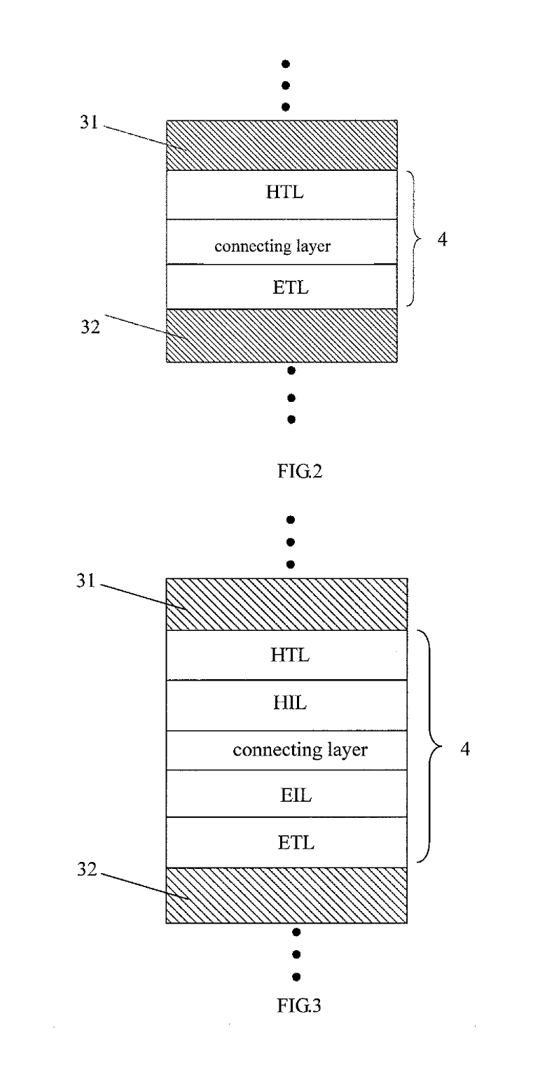

As an example, the connecting unit 4 comprises an electron transmission layer (ETL), a connecting layer, and a hole transmission layer (HTL), as illustrated in FIG. 2. As another example, the connecting unit 4 further comprises an electron injection layer (EIL) and a hole injection layer (HIL). For example, a connecting unit 4 as illustrated in FIG. 3 comprises an ETL, an EIL, a connecting layer, a HIL and a HTL. In practical applications, sequence of individual layers of the connecting unit is determined according to locations of the outmost cathode and anode, while sequences shown in FIGS. 2 and 3 are for illustrative purpose only. The connecting layer comprises for example organic or inorganic materials (such as metals, metal oxides). The connecting layer functions to generate charge carriers, such that the EIL or ETL can capture electrons and the HIL or HTL may capture holes.

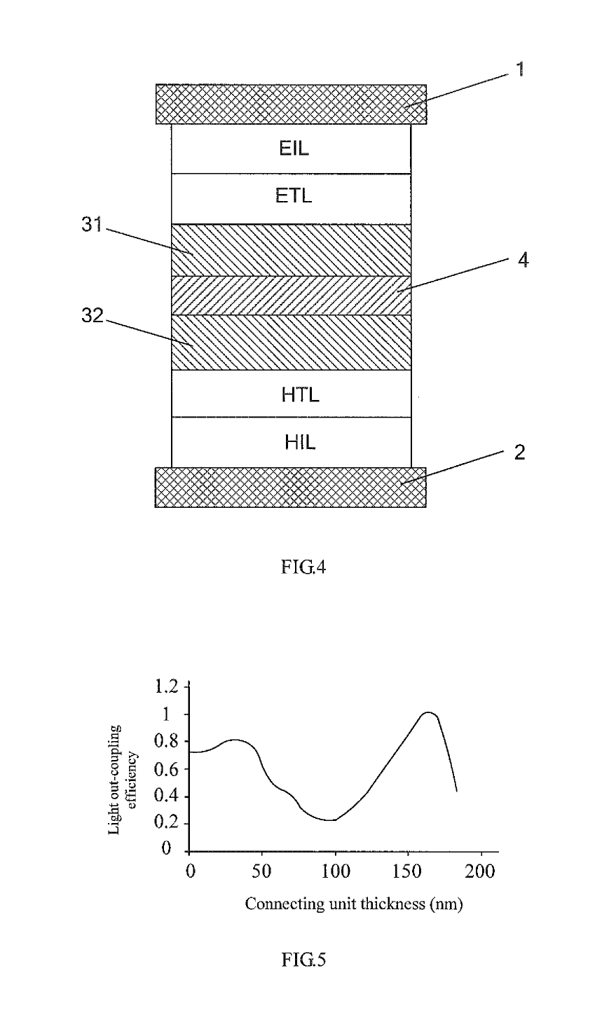

When the reflective electrode 1 is a cathode, an EIL and an ETL are disposed between the reflective electrode 1 and the neighboring organic emissive layer 31. In this case, the transmissive electrode 2 is an anode, and a HIL and a HTL are disposed between the transmissive electrode 2 functioning as the anode and the neighboring organic emissive layer 32 as illustrated in FIG. 4. Alternatively, when the reflective electrode 1 is an anode, a HIL and a HTL are disposed between the reflective electrode 1 and the neighboring organic emissive layer 31. In this case, the transmissive electrode 2 is a cathode, and an EIL and an ETL are disposed between the transmissive electrode 2 functioning as the cathode and the neighboring organic emissive layer 32. The connecting unit in FIG. 4 may be replaced with the connecting units of FIG. 2 or 3.

Considering the condition of standing wave in wave optics:

$$ϕ 1 + ϕ 2 + 2 \frac{2 π}{λ} n L cos θ = 2 m π$$

Wherein φ1 is phase difference of light emitted by an organic emissive layer before and after being reflected by the reflective electrode; φ2 is phase difference of light emitted by an organic emissive layer before and after being reflected by the transmissive electrode. The transmissive electrode has a relatively weaker reflectivity. λ is a wavelength of the light emitted by the organic emissive layer; n is an ambient refractive index; L is a distance between the reflective electrode and the transmissive electrode of the tandem OLED device, m is an arbitrary integer; and θ is an angle of light emission.

In the above equation, L and θ are variables which are easily adjustable. If the equation is true, L will vary with θ. Moreover, the following facts have to be considered: different organic emissive layers of the tandem OLED device emit light of different wavelengths and a material has different refractive indices n for different wavelengths. It thus follows that luminous intensities at varied viewing angles may be adjusted by adjusting L, and L is determined by the thicknesses of the organic emissive layer and the connecting unit. The thickness of the organic emissive layer is generally a constant, and the thickness of the connecting unit is the one more easily adjusted.

Based on the above analysis, the tandem OLED device is simulated by using an electromagnetic wave model. For example, by taking a tandem OLED device having only two organic emissive layers as an example, the thickness of the connecting unit being in a range of 0 to 170 nm is simulated. That is, the distance h between the two neighboring organic emissive layers is 0 to 170 nm. Light out-coupling efficiency of the tandem OLDE device is illustrated in FIG. 5, It is seen that the light out-coupling efficiency is optimal at 40 nm and 160 nm. With a connecting unit having such thicknesses, a relationship between the viewing angle and the luminous intensity is shown in Table 1.

TABLE 1

| Connecting | Viewing angle | | | |
|---|---|---|---|---|
| unit thickness | 0 degree | 20 degrees | 40 degrees | 60 degrees |
| 40 nm | 1000 cd | 998.92 cd | 875.26 cd | 587.67 cd |
| 160 nm | 1000 cd | 897.97 cd | 664.80 cd | 404.39 cd |

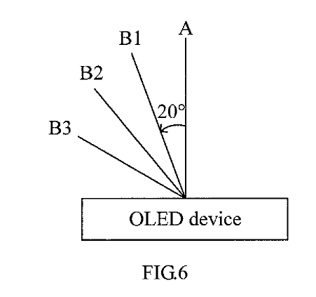

As illustrated in FIG. 6, at a point A with a viewing angle of 0 degree, the luminous intensity is 1000 cd. At a point B1 with a viewing angle of 20 degrees, the luminous intensity is 998.98 cd when h=40 nm, and the luminous intensity is 897.97 cd when h=160 nm. At a point B2 with a viewing angle of 40 degrees, the luminous intensity is 875.26 cd when h=40 nm, and the luminous intensity is 664.80 cd when h=160 nm. At a point B3 with a viewing angle of 60 degrees, the luminous intensity is 587.67 cd when h=40 nm, and the luminous intensity is 404.39 cd when h=160 nm.

It is seen that when the connecting unit is of a thickness of 40 nm, not only the luminous intensity is the highest, but also the attenuation of the luminous intensity is relatively slow when the view angle increases.

By simulating different tandem OLED devices in a similar way and analyzing the results, the following range for the distance between two neighboring organic light emissive layers is eventually obtained: ⅛(λ2−λ1)≦h≦⅓(λ2−λ1).

As an example, the n organic emissive layers are organic emissive layers respectively emitting light of different colors. For example, when n=2, the first light emitting layer is configured for emitting blue light, and the second light emitting layer is configured for emitting red light. The two light is mixed to form white light, such that light of different colors are obtained by a further color filter film in a display device. Alternatively, the first light emitting layer is configured for emitting blue light, and the second light emitting layer is configured for emitting green light. Alternatively, the first light emitting layer is configured for emitting green light, and the second light emitting layer is configured for emitting red light.

As an example, the n organic emissive layers emit light of the same color. For example, when n=2, both the first and second organic emissive layer emit blue light, though λ1<λ2.

As an example, in the above organic emissive layers, n=3. That is, the tandem OLED device comprises three organic emissive layers. Alternatively, the three organic emissive layers are respectively configured for emitting blue light, green light and red light. The distance h between two neighboring organic emissive layers of the three organic emissive layers is in the range of ⅛(λ2−λ1)≦h≦⅓(λ2−λ1). For example, a distance H_{B-G} between the blue organic emissive layer and the green organic emissive layer is in the range of ⅛(λ_{G}−λ_{B})≦h≦⅓(λ_{G}−λ_{B}). A distance h_{G-R} between the green organic emissive layer and the red organic emissive layer is in the range of ⅛(λ_{R}−λ_{G})≦h≦⅓(λ_{G}−λ_{G}), wherein λ_{B}, λ_{G} and λ_{R} are wavelengths with the maximum energy of spectrum energy distribution curves of light emitted by the blue, green and red organic light emitting layer, respectively.

It is seen from the simulation and analysis of the tandem organic OLED device of the embodiment that, while the viewing angle increases, the attenuation of luminous intensity is alleviated by defining the distance between neighboring organic emissive layers.

An embodiment of the invention further provides a display device comprising the above tandem OLED device.

The tandem OLED device of the display device has the same configuration and principle with the above embodiment and will not be elaborated here. The display device may be for example a display, a television, an E-paper, a digital photoframe, a mobile phone, a tablet PC or any product or component having a display function.

In the display device of the embodiment, the attenuation of luminous intensity is alleviated when the viewing angle increases by defining the distance between neighboring organic emissive layers.

What is described above is related to the illustrative embodiments of the disclosure only and not limitative to the scope of the disclosure; the scopes of the disclosure are defined by the accompanying claims.

This application claims the priority of Chinese Application No. 201310544720.X, filed on Nov. 5, 2013, and which application is incorporated herein by reference.

1. A tandem OLED device, comprising:
a reflective electrode;
a transmissive electrode;
n organic emissive layers disposed between the reflective electrode and the transmissive electrode, wherein n is an integer equal to or greater than 2; and
a connecting unit disposed between every two neighboring organic light emitting layers, wherein the connecting unit is configured for connecting the two neighboring organic light emitting layers;
wherein a distance h between the two neighboring organic light emitting layers satisfies the following equation: ⅛(λ2−λ1)≦h≦⅓(λ2−λ1), wherein an organic light emitting layer of the two neighboring organic light emitting layers which is closer to the reflective electrode is a first organic light emitting layer, λ1 is a wavelength with the maximum energy of a spectrum energy distribution curve of light emitted by the first organic light emitting layer; an organic light emitting layer of the two neighboring organic light emitting layers which is closer to the transmissive electrode is a second organic light emitting layer, λ2 is a wavelength with the maximum energy of a spectrum energy distribution curve of light emitted by the second organic light emitting layer, and λ2>λ1.

2. The tandem OLED device of claim 1, wherein the connecting unit comprises a connecting layer, an electron transmission layer and a hole transmission layer.

3. The tandem OLED device of claim 2, wherein the connecting unit further comprises an electron injection layer and a hole injection layer.

4. The tandem OLED device of claim 1, wherein the n organic light emitting layers emit light of different colors respectively.

5. The tandem OLED device of claim 4, wherein n=2.

6. The tandem OLED device of claim 5, wherein
the first light emitting layer is configured for emitting blue light, and the second light emitting layer is configured for emitting red light; or
the first light emitting layer is configured for emitting blue light, and the second light emitting layer is configured for emitting green light; or
the first light emitting layer is configured for emitting green light, and the second light emitting layer is configured for emitting red light.

7. The tandem OLED device of claim 1, wherein the reflective electrode is an anode, and the transmissive electrode is a cathode.

8. The tandem OLED device of claim 7, wherein a hole injection layer and a hole transmission layer are disposed between the reflective electrode and the first organic light emitting layer, and an electron injection layer and an electron transmission layer are disposed between the transmissive electrode and the second organic light emitting layer.

9. The tandem OLED device of claim 1, wherein the reflective electrode is a cathode, and the transmissive electrode is an anode.

10. The tandem OLED device of claim 9, wherein an electron injection layer and an electron transmission layer are disposed between the reflective electrode and the first organic light emitting layer, and a hole injection layer and a hole transmission layer are disposed between the transmissive electrode and the second organic light emitting layer.

11. The tandem OLED device of claim 1, wherein three organic light emitting layers are disposed between the reflective electrode and the transmissive electrode.

12. The tandem OLED device of claim 11, wherein the three organic light emitting layers are respectively configured for emitting blue light, green light and red light.

13. A display device, comprising the tandem OLED device of claim 1.

14. The display device of claim 13, wherein the connecting unit comprises a connecting layer, an electron transmission layer and a hole transmission layer.

15. The display device of claim 14, wherein the connecting unit further comprises an electron injection layer and a hole injection layer.

16. The display device of claim 13, wherein the n organic light emitting layers emit light of different colors respectively.

17. The display device of claim 16, wherein n=2.

18. The display device of claim 17, wherein
the first light emitting layer is configured for emitting blue light, and the second light emitting layer is configured for emitting red light; or
the first light emitting layer is configured for emitting blue light, and the second light emitting layer is configured for emitting green light; or
the first light emitting layer is configured for emitting green light, and the second light emitting layer is configured for emitting red light.
